(19) United States
(12) Patent Application Publication
(10) Pub. No.: US 2005/0263341 A1
(43) Pub. Date: Dec. 1, 2005

(54) Adjustable Speaker Mount

(75) Inventor: Dominick Joseph Minneci JR., Whiting, NJ (US)

Correspondence Address: DOMINICK J. MINNECI JR., 1380 BROOKLYN AVENUE, WHITING, NJ, 08759, US

(73) Assignee: Mr. Dominick Joseph Minneci, Whiting, NJ (US)

(21) Appl. No.: 10/709,787

(22) Filed: May 27, 2004

(51) Int. Cl. H05K 5/00

(52) U.S. Cl. 181/153; 181/154

(57) ABSTRACT

The Adjustable Speaker Mount is a two-piece adjustable speaker mounting device, consisting of a speaker mounting ring and a housing. The speaker mounting ring fits inside the housing in a fashion that allows it to be swiveled so the speaker can be aimed to improve sound quality by directing the sound emanating from the speaker toward the ear of a listener. The speaker mounting ring is comprised of a material that can be modified to allow the installation of several size speakers. In addition, the housing is comprised of a material that can be modified to allow modification for installation in a variety of enclosures and attached to said enclosure or surface by means of a housing mount.

### BACKGROUND OF INVENTION

1. Field of the Invention

The present invention generally relates to audio sound systems involving a speaker mounted in an enclosure or to a surface, particularly related to a speaker mounted in an enclosure or to a surface that is not directly aimed at the ear of the intended listener of the speaker.

Sound emanating from an audio loudspeaker is somewhat directional in nature. Sounds in the midrange and upper end of the audio spectrum (500 Hz to 20,000 Hz) are particularly directional. To obtain the most accurate sound reproduction possible through a cone or dome type loudspeaker, the speaker must be positioned properly, which usually means aiming the speaker at the ear of the listener. Most speaker mounting rings do notallow for proper positioning of the speaker.

2. Description of Related Devices

Devices have been invented to direct high frequency sounds towards the listener. For example, U.S. Pat. No. 5,133,428 to Perrson describes a device that incorporates a small high frequency dome type speaker in a movable housing, but it is limited to specific size, shape, and style speakers and mounting surfaces, does not provide provisions for cone type speakers with mounting rings, does not allow the speaker to be easily removed from its housing, and does not facilitate installation in the existing mounting area of a cone type speaker with a mounting ring.

U.S. Pat. No. 4,630,303 to Tanno describes a speaker system for automotive applications and includes a high frequency speaker and a midrange/low frequency speaker, where a motor and a series of gears is used to reposition the high frequency speaker to redirect its sound. The Tanno device is complicated, does not allow for modification for multiple speaker types and mounting surfaces, has limited range of motion for speaker adjustment, and provides for adjustment of the high frequency speaker only.

### BRIEF DESCRIPTION OF DRAWINGS

FIG. 1 is a perspective view of the device made in accordance with the claims of the present invention;

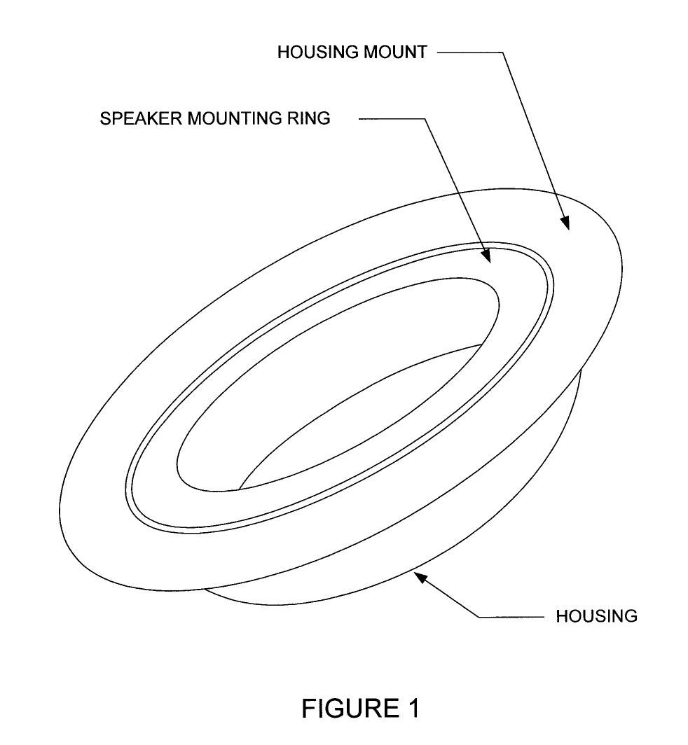

FIG. 2 is a cut-away view through the center of the device of FIG. 1;

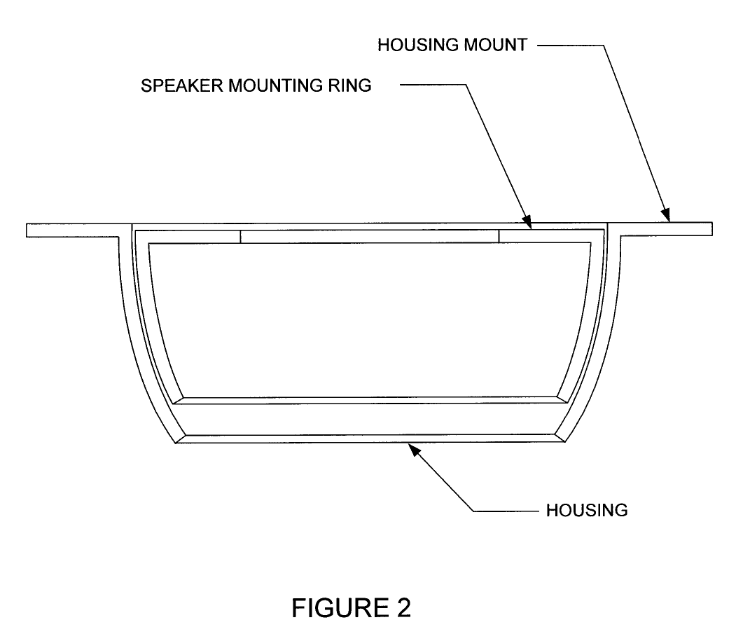

FIG. 3 is an exploded view of the two pieces that comprise the device in FIG. 1;

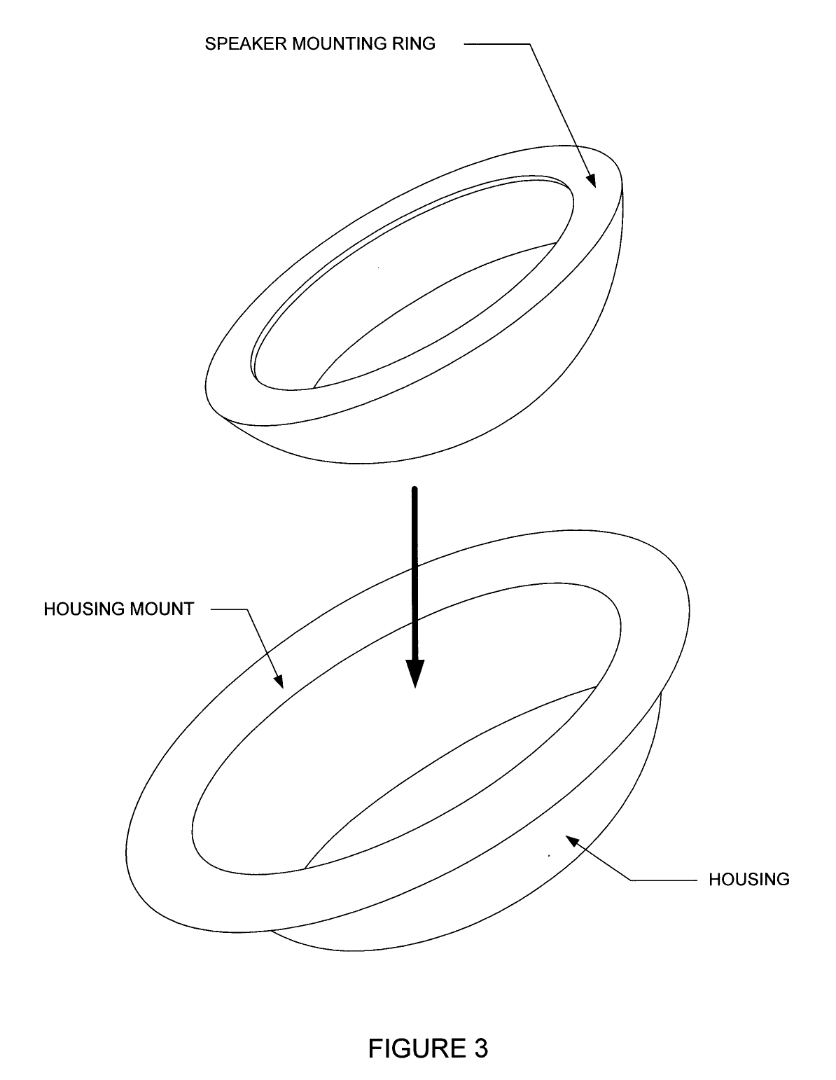

FIG. 4 is an example installation of a speaker installed and angled inside the device in FIG. 1.

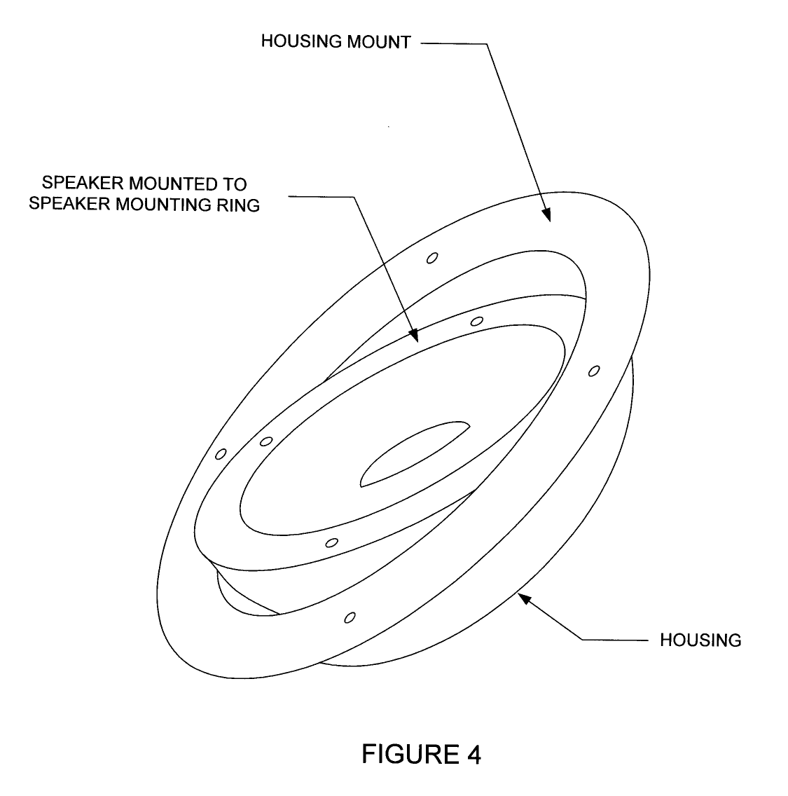

### DETAILED DESCRIPTION

This invention overcomes the deficiencies of other speaker positioning devices by having the ability to be used for precisely angling a speaker capable of reproducing the entire audio frequency range, where the speaker itself can be interchanged without disassembling the device or disturbing the set angle of the device, and can be mounted in a new or existing speaker cutout or hole like what is currently found in the speaker mounting area of an automobile or other motor vehicle, watercraft, desktop speaker enclosure, floor standing speaker enclosure, wall mounted speaker or wall mounted speaker enclosure, or any surface in which a speaker is mounted.

This invention also provides for the installation of multiple size speakers, regardless of whether said speaker is intended for high or low frequency reproduction. The speaker mounting ring can be easily modified by the installer, without limiting its functionality, to accept said speaker.

This invention allows for easy modification of its housing, without limiting its functionality, to facilitate installation of the device to a wide variety of mounting surfaces, especially those with obstructions behind the mounting surface, as is commonly found, for example, behind a speaker mounted in an automobile door.

1. A device,
comprised of a speaker mounting ring in which a speaker is affixed;
that fits into a housing in a manner to allow angular and circular movement;
constructed of a semi-pliable material to allow modification for mounting of various speaker sizes and types, and installation of the device into various enclosures.

2. Device in claim 1, to be used for aiming speakers at a listeners ear in any listening environment, such as an automobile or other motor vehicle, watercraft, desktop speaker enclosure, floor standing speaker enclosure, wall mounted speaker or wall mounted speaker enclosure, or any surface in which a speaker can be mounted.

3. Device in claim 2, where speaker mounted to the speaker mounting ring can be manually adjusted bu means of rotating or angling the speaker mounting ring within the housing.

4. Device in claim 3, where position of speaker mounting ring can be fixed to the housing to hold speaker mounting ring firmly in place.
